(19) United States
(12) Patent Application Publication
(10) Pub. No.: US 2003/0235777 A1
(43) Pub. Date: Dec. 25, 2003

(54) Phenolic polymers, methods for synthesis thereof and photoresist compositions comprising same

(75) Inventors: Dana A. Gronbeck, Holliston, MA (US); George G. Barclay, Jefferson, MA (US)

Correspondence Address: EDWARDS & ANGELL, LLP, Dike, Bronstein, Roberts & Cushman, IP Group, P.O. Box 9169, Boston, MA, 02209, US

(73) Assignee: Shipley Company, L.L.C., Marlborough, MA

(21) Appl. No.: 10/327,589

(22) Filed: Dec. 20, 2002

Related U.S. Application Data
(60) Provisional application No. 60/344,893, filed on Dec. 31, 2001.

(51) Int. Cl. G03F 7/038

(52) U.S. Cl. 430/270.1; 430/905

(57) ABSTRACT

The invention provides phenolic polymers, and methods for synthesis and photoresists that comprise such polymers. Synthetic methods of the invention include providing a polymer that contains esterified meta-phenolic units, and removing the ester group preferably by hydrolysis to provide a polymer with meta-phenolic units.

### BACKGROUND OF THE INVENTION

1. Field of the Invention

The present invention relates to phenolic polymers, methods for preparation of phenolic polymers, and photoresist compositions that comprise such phenolic polymers. Preferred polymers of the invention comprise meta-hydroxyphenyl units (or corresponding esterified groups) and alicyclic units such as adamantyl.

2. Background

Photoresists are photosensitive films for transfer of images to a substrate and form negative or positive images. After coating a photoresist on a substrate, the coating is exposed through a patterned photomask to a source of activating energy such as ultraviolet light to form a latent image in the photoresist coating. The photomask has areas opaque and transparent to activating radiation that define a desired image to be transferred to the underlying substrate. A relief image is provided by development of the latent image pattern in the resist coating. The use of photoresists is generally described, for example, by Deforest, Photoresist Materials and Processes, McGraw Hill Book Company, New York (1975), and by Moreau, Semiconductor Lithography, Principals, Practices and Materials, Plenum Press, New York (1988).

While currently available photoresists are suitable for many applications, current resists also can exhibit significant shortcomings, particularly in high performance applications such as e.g. formation of highly resolved sub-half micron and sub-quarter micron features.

More recently, chemically-amplified-type resists have been increasingly employed. In the case of positive chemically-amplified resists, certain cationic photoinitiators have been used to induce cleavage of certain “blocking” groups pendant from a photoresist binder, or cleavage of certain groups that comprise a photoresist binder backbone. See, for example, U.S. Pat. Nos. 5,075,199; 4,968,581; 4,883,740; 4,810,613; and 4,491,628, and Canadian Patent Application 2,001,384. See also R. D. Allen et al., Proceedings of SPIE, 2724:334-343 (1996); and P. Trefonas et al. Proceedings of the 11th International Conference on Photopolymers (Soc. Of Plastics Engineers), pp 44-58 (Oct. 6, 1997).

WO 99/57163 reports particular hydrolysis of copolymers of para-acetoxystyrene and certain alkylacrylates.

### SUMMARY OF THE INVENTION

We have now discovered new methods for preparation of phenolic polymers that includes hydrolysis of ester phenolic protecting groups such as acetoxy.

More particularly, in a first aspect, methods of the invention include providing a polymer that contains esterified meta-phenolic units, and removing the ester group preferably by hydrolysis to provide a polymer with meta-phenolic units. Preferably, the polymer contains meta-acetoxyphenyl units that are hydrolyzed to meta-phenolic units, and preferably the polymer contains additional units such as para-hydroxyphenyl units, or photoacid-labile groups such as alkyl acrylate units.

In a further aspect, the invention provides methods for synthesis of a phenolic polymer that contains photoacid-labile units that comprise an alicyclic hydrocarbon group, preferably a tertiary alicyclic ester group, that preferably has two or more fused or bridged rings. Preferred alicyclic photoacid-labile ester groups also are of significant size, e.g. the alicyclic group will have a molecular volume of at least about 125 cubic angstroms (Å³).

Preferred tertiary ester groups include optionally substituted fencyl groups, particularly ethyl fencyl; optionally substituted alkyl adamantyl, particularly a methyladamantyl leaving group (where the ester oxygen is linked to the tertiary carbon of the methyladamantyl moiety such as may be provided by polymerization of 2-methyl-2-adamantyl acrylate or 2-methyl-2-adamantyl methacrylate); optionally substituted tricyclo decanyl; and optionally substituted pinnanyl.

Polymers of the invention have a variety of other units, e.g. cyano units such as may be provided by polymerization of acrylonitrile or methyl acrylonitrile; styrene and substituted styrene units; non-photoacid labile alicyclic units such as may be provided by polymerization of cyclic olefins e.g. vinyl isobornyl, etc.; carboxylic acid units; anhydride units such as itaconic anhydride units; and the like.

Preferred polymers of the invention comprise units of: 1) meta-hydroxyphenyl units, 2) para-hydroxyphenyl units; and 3) alicyclic units, particularly photoacid-labile units that comprise an alicyclic group. Such a polymer may be provided e.g. by reacting a 1-vinyl-3-esterphenyl such as 1-vinyl-3-acetoxyphenyl; a 1-vinyl-4-esterphenyl such as 1-vinyl-4-acetoxyphenyl; and an alicyclic acrylate such as methyladamantyl acrylate or methyladamantyl methacrylate. It should be understood that references herein an acrylate compound are inclusive of substituted acrylates including acrylates having substitution of unsaturated carbons such as methacrylates. Similarly, references herein to vinylphenyl groups or compounds are inclusive of compounds having substitution of the vinylic carbons, e.g. an alpha-methyl styrenic compound.

Additionally, methods are provided for forming relief images, including methods for forming a highly resolved relief image such as a pattern of lines where each line has essentially vertical sidewalls and a line width of about 0.40 microns or less, and even a width of about 0.25 or 0.20 microns or less. The invention further provides articles of manufacture comprising substrates such as a microelectronic wafer substrate or liquid crystal display or other flat panel display substrate having coated thereon a polymer, photoresist or resist relief image of the invention. Other aspects of the invention are disclosed infra.

### DETAILED DESCRIPTION OF THE INVENTION

As discussed above, we have discovered that methods that include removing preferably by hydrolysis ester moieties of esterified meta-phenolic units to provide a polymer with meta-phenolic units (i.e. 3—OHC₆H₄— polymer units). Preferably, the polymer contains meta-acetoxyphenyl units that are hydrolyzed to meta-phenolic units, and preferably the polymer contains additional units such as para-hydroxyphenyl units, or photoacid-labile groups such as alkyl acrylate units.

In particular, the invention provides methods for polymer synthesis that comprise polymerizing a 1-vinyl-3-esterphenyl compound with one or more other distinct monomers to provide a polymer having meta-esterphenyl repeat units; and treating the polymer to provide meta-hydroxyphenyl repeat units.

Particularly preferred meta-esterphenyl polymer units that are treated (hydrolyzed) in accordance with the invention include those of the formula meta—RC(═O)O—C₆H₄— where R is optionally substituted alkyl such as C₁₋₈alkyl or optionally substituted carbocyclic aryl such as phenyl or naphthyl, preferably alkyl such as C₁₋₃alkyl, particularly acetoxy. Suitable substituents of substituted R groups include halogen (F, Cl, Br, I), C₁₋₆alkoxy, nitro, C₁₋₆alkyl and the like.

As exemplified in that above formula, the ester group for deprotection treatment preferably provides a hydroxyphenyl group. Thus, the ester carboxyl (i.e. the following underlined oxygen —C(═O)O—) of the ester is the direct phenyl ring substituent.

References herein to a meta-substituted phenyl group or component typically indicates that the group or compound is unsubstituted at the para-ring position, although the group or compound may suitably have substitution at the other meta position or either or both of the ortho ring positions. In general, however, the meta-substituted phenyl group or compound is only substituted at a single meta-ring position by a single hydroxy or protected hydroxy (e.g. acetoxy) group, and the other ring positions not linked to the polymer are unsubstituted (i.e. only hydrogen).

The removal of meta-phenolic ester groups in accordance with the invention can be conducted by a variety of methods. For instance, a polymer containing meta-esterphenyl units can be dissolved or more typically dispersed in a suitable solvent, preferably with base. Suitable solvents for dissolving or dispersing the polymer include alcohols e.g. e.g. methanol, ethanol, isopropanol, 1-methoxy-2-propanol, 1-ethoxy-2-propanol, and the like. Suitable bases include e.g. a metal alkoxide such as where the alkali metal is Li, Na, K, Rb, Cs; and the alkoxide is methoxide, ethoxide, isopropoxide, t-butoxide and the like, with sodium methoxide being generally preferred. If a metal alkoxide is the base, preferably a crown ether (e.g. 18-crown-6) is also employed in the reaction solution.

The deprotection reaction also can be conducted under substantially neutral conditions, without the use of an added base. However, the reaction typically will proceed more readily with an added base such as sodium methoxide. A relatively mild base is generally preferred, e.g. a base having a pKa of about 13, 12 or less (lower number), or 11, 10, or 9 or less. As used herein the term “pKa” is used in accordance with its art recognized meaning, i.e., pKa is the negative log (to the base 10) of the dissociation constant of the organic salt in aqueous solution at about room temperature (25° C.).

Preferably, the deprotection reaction is conducted at an elevated temperature and for an extended period of time. For instance, the reaction solution can be maintained at reflux for 1 or more hours, preferably at least about 5 or 10 hours, more preferably at least about 11, 12, 13, 14 or 15 hours.

Thereafter, the reaction solution is suitably cooled to room temperature. If a base such as a metal alkoxide was employed, preferably the base is removed from the reaction mixture. Ion exchange is a particularly preferred method for removal of a metal alkoxide or other base. Suitable ion exchange materials include a strong cation resin e.g. IRN-77; a weak cation resin, e.g. IRC-50; or an acid washed chelating iminodiacetic acid such as IRC-748.

Polymers are preferably treated with an ion exchange material during or promptly after (within 1, 6, 12, 18, 24 or 48 hours of reaction completion) completion of the de-esterification reaction of the formed polymer.

The ion exchange material is preferably pre-treated prior to use in the methods of the invention. Preferred pretreatment of ion exchange beads or other ion exchange materials include washing with water, preferably deionized water, coupled with washing with one or more organic solvents. Preferably ion exchange material is washed successively (e.g. 2, 3, 4, 5, or more successive washings), followed by successive washings (e.g. 2, 3, 4, 5, or more successive washings) with one or more distinct organic solvents. Preferably, the ion exchange material is washed with water followed by one or more organic solvents, preferably one or two organic solvents. For each washing, the ion exchange beads or other materials are preferably slurried or otherwise agitated in the washing water or organic solvent for a period of time, e.g. 1 to about 10 minutes or more, more typically 5, 6, 7, 8, 9, or 10 or more minutes. The washing water or solvent can be removed after each wash e.g. by filter of the ion exchange material. Preferred solvents for washing of ion exchange material include acetone and alcohols such as isopropyl alcohol, ethanol and the like.

The reaction mixture can be treated with an ion exchange material by any of a number of methods. A preferred treatment method includes addition of ion exchange beads to a reaction solution and agitation of that mixture for a period of time, e.g. 1, 2, 3, 4, 5 or more hours. The solution then can be filtered to remove the ion exchange material.

The deprotected or de-esterified phenolic polymer can be isolated by a variety of methods. For example, the organic solvent polymer solution can be admixed with water to precipitate the polymer. The organic solvent also can be removed under reduced pressure to precipitate the polymer.

As discussed, preferred photoacid-labile ester groups contain a tertiary alicyclic hydrocarbon ester moiety. Preferred tertiary alicyclic hydrocarbon ester moieties are polycyclic groups such adamantyl, ethylfencyl or a tricyclo decanyl moiety. References herein to a “tertiary alicyclic ester group” or other similar term indicate that a tertiary alicyclic ring carbon is covalently linked to the ester oxygen, i.e. —C(═O)O—TR′ where T is a tertiary ring carbon of alicyclic group R′. In at least many cases, preferably a tertiary ring carbon of the alicyclic moiety will be covalently linked to the ester oxygen, such as exemplified by the below-depicted specifically preferred polymers. However, the tertiary carbon linked to the ester oxygen also can be exocyclic to the alicyclic ring, typically where the alicyclic ring is one of the substituents of the exocyclic tertiary carbon. Typically, the tertiary carbon linked to the ester oxygen will be substituted by the alicyclic ring itself, and/or one, two or three alkyl groups having 1 to about 12 carbons, more typically 1 to about 8 carbons, even more typically 1, 2, 3 or 4 carbons. The alicyclic group also preferably will not contain aromatic substitution. The alicyclic groups may be suitably monocyclic, or polycyclic, particularly bicyclic or tricyclic groups.

Preferred alicyclic moieties (e.g. group TR′ of —C(═O)O—TR′) of photoacid labile ester groups of polymers of the invention have rather large volume. It has been found that such bulky alicyclic groups can provide enhanced resolution when used in copolymers of the invention.

More particularly, preferred alicyclic groups of photoacid labile ester groups will have a molecular volume of at least about 125 or about 130 Å³, more preferably a molecular volume of at least about 135, 140, 150, 155, 160, 165, 170, 175, 180, 185, 190, 195, or 200 Å³. Alicyclic groups larger than about 220 or 250 Å³ may be less preferred, in at least some applications. References herein to molecular volumes designate volumetric size as determined by standard computer modeling, which provides optimized chemical bond lengths and angles. A preferred computer program for determining molecular volume as referred to herein is Alchemy 2000, available from Tripos. For a further discussion of computer-based determination of molecular size, see T Omote et al, Polymers for Advanced Technologies, volume 4, pp. 277-287.

Preferred polymers of the invention may contain 3, 4 or 5 distinct repeat units, i.e. preferred are terpolymers, tetrapolymers and pentapolymers. One of the units will be a phenolic unit or corresponding esterified (protected) phenyl group thereof. Preferably at least one of the other groups will comprise a tertiary alicyclic group, preferably as a leaving group component of a photoacid labile unit, e.g. the tertiary alicyclic group can be a component of a photoacid-labile ester such as provide by polymerization of an acrylate compound.

Thus, preferred photoacid-labile groups of polymers of the invention include esters that contain a tertiary alicyclic group. Such photoacid-labile esters may be directly pendant from a carbon alicyclic, heteroalicyclic or other polymer unit (e.g. where the photoacid-labile group is of the formula —C(═O)OR, where R is tert-butyl or other non-cyclic alkyl group, or a tertiary alicyclic group and is directly linked to the polymer unit), or the ester moieties may be spaced from the from a heteroalicyclic or carbon alicyclic polymer unit, e.g. by an optionally alkylene linkage (e.g. —(CH₂)₁₋₈C(═O)OR, where R is tert-butyl or other non-cyclic alkyl group, or a tertiary alicyclic group). Such photoacid-labile groups also suitably may be contain fluorine substitution at available positions.

As discussed, preferred photoacid-labile ester groups contain a tertiary alicyclic hydrocarbon ester moiety. Preferred tertiary alicyclic hydrocarbon ester moieties are polycyclic groups such adamantyl, ethylfencyl or a tricyclo decanyl moiety. References herein to a “tertiary alicyclic ester group” or other similar term indicate that a tertiary alicyclic ring carbon is covalently linked to the ester oxygen, i.e. —C(═O)O—TR′ where T is a tertiary ring carbon of alicyclic group R′. In at least many cases, preferably a tertiary ring carbon of the alicyclic moiety will be covalently linked to the ester oxygen, such as exemplified by the below-depicted specifically preferred polymers. However, the tertiary carbon linked to the ester oxygen also can be exocyclic to the alicyclic ring, typically where the alicyclic ring is one of the substituents of the exocyclic tertiary carbon. Typically, the tertiary carbon linked to the ester oxygen will be substituted by the alicyclic ring itself, and/or one, two or three alkyl groups having 1 to about 12 carbons, more typically 1 to about 8 carbons, even more typically 1, 2, 3 or 4 carbons. The alicyclic group also preferably will not contain aromatic substitution. The alicyclic groups may be suitably monocyclic, or polycyclic, particularly bicyclic or tricyclic groups.

Preferred alicyclic moieties (e.g. group TR′ of —C(═O)O—TR′) of photoacid labile ester groups of polymers of the invention have rather large volume. It has been found that such bulky alicyclic groups can provide enhanced resolution when used in copolymers of the invention.

More particularly, preferred alicyclic groups of photoacid labile ester groups will have a molecular volume of at least about 125 or about 130 Å³, more preferably a molecular volume of at least about 135, 140, 150, 155, 160, 165, 170, 175, 180, 185, 190, 195, or 200 Å³. Alicyclic groups larger than about 220 or 250 Å³ may be less preferred, in at least some applications. References herein to molecular volumes designate volumetric size as determined by standard computer modeling, which provides optimized chemical bond lengths and angles. A preferred computer program for determining molecular volume as referred to herein is Alchemy 2000, available from Tripos. For a further discussion of computer-based determination of molecular size, see T Omote et al, Polymers for Advanced Technologies, volume 4, pp. 277-287.

Particularly preferred tertiary alicyclic groups of photoacid-labile units include the following, where the wavy line depicts a bond to the carboxyl oxygen of the ester group, and R is suitably optionally substituted alkyl, particularly C₁₋₈ alkyl such as methyl, ethyl, etc.

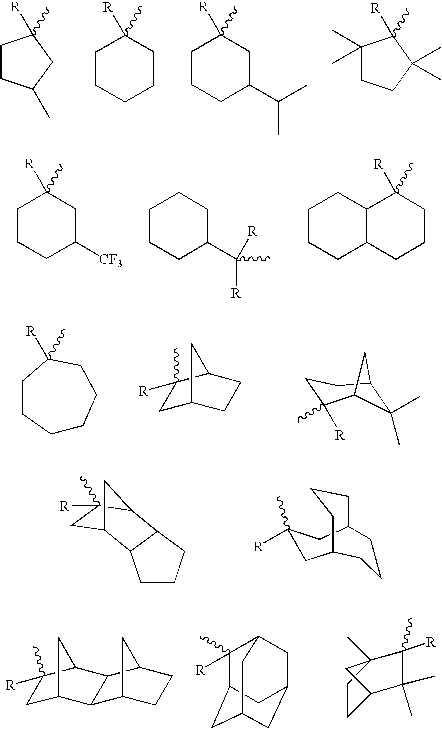

Polymers of the invention also may contain photoacid-labile groups that do not contain an alicyclic moiety. For example, polymers of the invention may contain photoacid-labile ester units, such as a photoacid-labile alkyl ester. Generally, the carboxyl oxygen (i.e. the carboxyl oxygen as underlined as follows: —C(═O)O) of the photoacid-labile ester will be covalently linked to the quaternary carbon. Branched photoacid-labile esters are generally preferred such as t-butyl and —C(CH₃)₂CH(CH₃)₂.

In this regard, polymers used in resists of the invention may contain distinct photoacid-labile groups, i.e. the polymer may contain two or more ester groups that have distinct ester moiety substitutions e.g. one ester may have an alicyclic moiety and another ester may have an acyclic moiety such as t-butyl, or the polymer may contain both ester and other functional groups that are photoacid-labile such as acetals, ketals and/or ethers.

Polymers of the invention also may contain additional units such as cyano units, lactone units or anhydride units. For example, acrylonitrile or methacrylonitrile may be polymerized to provide pendant cyano groups, or maleic anhydride may be polymerized to provide a fused anhydride unit.

After providing a polymer of the invention, the polymer may be formulated with other components to provide a photoresist composition. More particularly, the treated resin is admixed with a photoactive component, typically one or more photoacid generator compounds, and solvent to provide a liquid photoresist formulation.

Preferably a photoacid generator or other photoactive compound will be present in a resist composition in an amount sufficient to generate a latent image in a coating layer. A variety of photoacid generators may be employed. For example, sulfonate compounds are preferred PAGs, particularly sulfonate salts. Two specifically preferred agents are of the following structures 1 and 2:

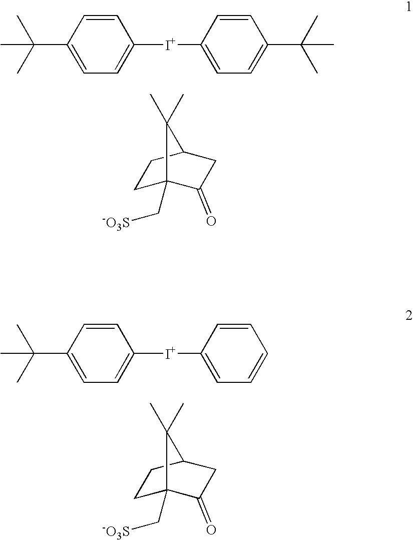

Such sulfonate compounds can be prepared as disclosed in European Patent Application 96118111.2 (publication number 0783136), which details the synthesis of above PAG 1.

Also suitable are the above two iodonium compounds complexed with anions other than the above-depicted camphorsulfonate groups. In particular, preferred anions include those of the formula RSO₃— where R is adamantane, alkyl (e.g. C₁₋₁₂ alkyl) and perfluoroalkyl such as perfluoro (C₁₋₁₂alkyl), particularly perfluorooctanesulfonate, perfluorobutanesulfonate and the like.

Additional preferred PAGs for use in photoresists of the invention include imidosulfonates such as compounds of the following formula:

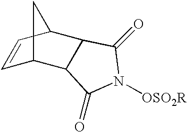

wherein R is camphor, adamantane, alkyl (e.g. C₁₋₁₂ alkyl) and perfluoroalkyl such as perfluoro(C₁₋₁₂alkyl), particularly perfluorooctanesulfonate, perfluorononanesulfonate and the like. A specifically preferred PAG is N-[(perfluorooctanesulfonyl)oxy]-5-norbornene-2,3 -dicarboximide.

Onium salts are preferred acid generators for resists prepared in accordance with the invention. Onium salts that weakly nucleophilic anions have been found to be particularly suitable. Examples of such anions are the halogen complex anions of divalent to heptavalent metals or non-metals, for example, Sb, Sn, Fe, Bi, Al, Ga, In, Ti, Zr, Sc, D, Cr, Hf, and Cu as well as B, P, and As. Examples of suitable onium salts are diaryl-diazonium salts and onium salts of group Va and B, Ia and B and I of the Periodic Table, for example, halonium salts, quaternary ammonium, phosphonium and arsonium salts, aromatic sulfonium salts and sulfoxonium salts or selenium salts. Examples of suitable preferred onium salts can be found in U.S. Pat. Nos. 4,442,197; 4,603,101; and 4,624,912.

Other useful acid generators include the family of nitrobenzyl esters, and the s-triazine derivatives. Suitable s-triazine acid generators are disclosed, for example, in U.S. Pat. No. 4,189,323.

Photoresists prepared in accordance with the invention may contain other components, e.g., a dye compound. Other optional photoresist materials include anti-striation agents, plasticizers, speed enhancers, etc. Such optional additives typically will be present in minor concentration in a photoresist composition except for fillers and dyes which may be present in relatively large concentrations such as, e.g., in amounts of from about 5 to 30 percent by weight of the total weight of a resist's dry components.

The resist compositions of the invention can be readily prepared by those skilled in the art. Typically, the solids content of a resist composition varies between about 5 and 35 percent by weight of the total weight of the photoresist composition. The resin and PAG components should be present in amounts sufficient to provide a film coating layer and formation of good quality latent and relief images.

If desired, the resist composition may be filtered prior to use, or a solution of the resist resin binder may be filtered prior to addition of the photoactive component or other additives during formulation of the resist.

Photoresist compositions prepared in accordance with the invention can be used in accordance with generally known procedures. Thus, for example, a liquid coating composition of the invention is applied to a substrate such as by spinning, dipping, roller coating or other conventional coating technique. When spin coating, the solids content of the coating solution can be adjusted to provide a desired film thickness based upon the specific spinning equipment utilized, the viscosity of the solution, the speed of the spinner and the amount of time allowed for spinning.

The resist compositions of the invention are suitably applied to substrates conventionally used in processes involving coating with photoresists. For example, the composition may be applied over silicon or silicon dioxide wafers for the production of microprocessors and other integrated circuit components. Aluminum-aluminum oxide, gallium arsenide, ceramic, quartz or copper substrates also may be employed. Substrates used for liquid crystal display and other flat panel display applications are also suitably employed, e.g. glass substrates, indium tin oxide coated substrates and the like.

Following coating of the photoresist onto a surface, it is dried by heating to remove the solvent until preferably the photoresist coating is tack free. Thereafter, it is imaged through a mask in conventional manner. The exposure is sufficient to effectively activate the photoactive component of the photoresist system to produce a patterned image in the resist coating layer and, more specifically, an activating exposure wavelength is employed and the exposure energy typically ranges from about 10 to 300 mJ/cm2, dependent upon the exposure tool and the components of the photoresist composition.

Following exposure, a film layer of a resist composition can be baked e.g. at temperatures ranging from about 70° C. to about 160° C. Thereafter, the film is developed, typically with an alkaline aqueous based developer such as a tetra-alkyl ammonium hydroxide aqueous solution. Following development of the photoresist coating over the substrate, the developed substrate may be selectively processed on those areas bared of resist, for example by chemically etching or plating substrate areas bared of resist in accordance with procedures known in the art. For the manufacture of microelectronic substrates, e.g., the manufacture of silicon dioxide wafers, suitable etchants include a plasma gas etch (e.g. an oxygen plasma etch) and a hydrofluoric acid etching solution. After such processing, resist may be removed from the processed substrate using known stripping procedures.

All documents mentioned herein are incorporated herein in their entirety by reference.

The following non-limiting examples are illustrative of the invention.

### EXAMPLE 1

### Synthesis and Deprotection of Meta-Esterphenyl Polymer

4-Acetoxystyrene (21.63 g, 133.33 mmols), 3-acetoxystyrene (21.63 g, 133.33 mmols) and t-butylacrylate (8.55 g, 66.67 mmols) were dissolved in 175 mL of 1:1 MeOH and THF. The reaction solution was then deoxygenated by gently bubbling a stream of N₂ through the stirring solution for 20 minutes and then placing it under a blanket of N₂. The polymerization solution was then brought to a gentle reflux t-Butyl peroxypivalate (tBPP, 2.71 g, 23.33 mmols) was then added to the gently refluxing mixture. The polymerization was then refluxed with stirring for about 18 hours. The refluxing polymer solution was diluted by the addition of 30 mL of 1:1 MeOH and THF. To the polymer solution was added NaOMe (0.5 g, 25% in MeOH, 500 ppm in excess of the amount to neutralize the residual acetic acid of the monomer). The refluxing was continued for about 15 hours and the polymer solution cooled to room temperature. To the polymer solution, 10 gms of conditioned IRN-77 beads (strongly acidic, cation exchange beads; which were conditioned prior to use as described below) were added and the mixture stirred gently for 2 hours. The polymer solution was then filtered and the polymer isolated by precipitation into eight-fold excess of deionized H₂O. The polymer was filtered, washed well with H₂O and air-dried. The final drying was carried out in a vacuum oven at 70° C. for 24 hours.

The IRN-77 beads were conditioned as follows prior to use.

a) The LRN-77 (2150 gms) beads were well soaked in deionized H₂O and the H₂O removed after about 5-7 minutes of gentle stirring. This deionized H₂O soaking procedure was repeated 5 times.

b) The IRN-77 beads were then well soaked in acetone and the acetone removed after ca. 5-7 minutes of gentle stirring. This acetone soaking procedure was repeated 3 times.

c) The IRN-77 beads were then well soaked in isopropyl alcohol and the isopropyl alcohol removed after about 5-7 minutes of gentle stirring. This isopropyl alcohol soaking procedure was repeated 2 times. The beads were then drained of the isopropyl alcohol and then used immediately in the above procedure.

The foregoing description of the invention is merely illustrative thereof, and it is understood that variations and modifications can be effected without departing from the spirit or scope of the invention as set forth in the following claims.

What is claimed is:

1. A method for preparation of a photoresist composition comprising:
(a) providing a resin obtained by a process comprising:
(i) polymerizing a 1-vinyl-3-esterphenyl compound with one or more other distinct monomers to provide a polymer having meta-esterphenyl repeat units; and
(ii) treating the polymer to provide meta-hydroxyphenyl repeat units; and
(b) admixing the polymer having meta-hydroxyphenyl repeat units with a photoactive component to provide a photoresist composition.

2. The method of claim 1 wherein the polymer the meta-esterphenyl units are of the formula meta—RC(═O)O—C₆H₄— where R is optionally substituted alkyl or optionally substituted carbocyclic aryl.

3. The method of claim 2 wherein R is C₁₋₈alkyl.

4. The method of any one of claims 1 through 3 wherein the meta-ester groups are acetoxy groups.

5. The method of any one of claims 1 through 4 wherein the polymer meta-ester units are hydrolyzed in the presence of base to provide hydroxy units.

6. The method of claim 5 wherein the base is an alkoxide.

7. The method of claim 5 wherein the base is a metal C₁₋₂alkoxide.

8. The method of claim 5 wherein the base is sodium methoxide.

9. The method of claim 5 wherein the base has a pKa of less than about 13.

10. The method of any one of claims 1 through 9 wherein the polymer comprises tertiary alicyclic units.

11. The method of any one of claims 1 through 10 wherein the polymer comprises units provided by polymerization of an alicyclic acrylate compound.

12. The method of claim 10 or 11 wherein the alicyclic units comprise an optionally substituted adamantyl group.

13. The method of claim 10 or 11 wherein the alicyclic units comprise an optionally substituted pinnanyl, optionally substituted fencyl or optionally substituted dodecanyl.

14. The method of any one of claims 1 through 13 wherein the treated polymer further comprises para-hydroxyphenyl units.

15. The method of any one of claims 1 through 13 wherein the treated polymer comprises repeat units of: i) meta-hydroxyphenyl; ii) para-hydroxyphenyl; and iii) alicyclic units.

16. The method of claim 15 wherein the alicyclic units are photoacid-labile.

17. The method of any one of claims 1 through 16 wherein the polymer is treated with ion exchange material during or after de-esterification.

18. The method of any one of claims 1 through 17 wherein the polymer is admixed with one or more photoacid generator compounds to provide a photoresist composition.

19. A method for synthesis of a polymer comprising meta-hydroxyphenyl units and photoacid-labile groups that comprise an alicyclic group, the method comprising:
(a) polymerizing a 1-vinyl-3-esterphenyl compound with one or more other distinct monomers to provide a polymer having meta-esterphenyl repeat units; and
(b) treating the polymer to provide meta-hydroxyphenyl repeat units;

20. The method of claim 19 wherein the polymer the meta-esterphenyl units are of the formula meta—RC(═O)O—C₆H₄— where R is optionally substituted alkyl or optionally substituted carbocyclic aryl.

21. The method of claim 20 wherein R is C₁₋₈alkyl.

22. The method of any one of claims 19 through 21 wherein the meta-ester groups are acetoxy groups.

23. The method of any one of claims 19 through 22 wherein the polymer meta-ester units are hydrolyzed in the presence of base to provide hydroxy units.

24. The method of claim 23 wherein the base is an alkoxide.

25. The method of claim 23 wherein the base is a metal C₁₋₂alkoxide.

26. The method of claim 23 wherein the base is sodium methoxide.

27. The method of claim 23 wherein the base has a pKa of less than about 13.

28. The method of any one of claims 19 through 27 wherein the polymer comprises tertiary alicyclic units.

29. The method of any one of claims 19 through 27 wherein the polymer comprises units provided by polymerization of an alicyclic acrylate compound.

30. The method of claim 28 or 29 wherein alicyclic units of the polymer comprise an optionally substituted adamantyl group.

31. The method of claim 28 or 29 wherein the alicyclic units comprise an optionally substituted pinnanyl, optionally substituted fencyl or optionally substituted dodecanyl.

32. The method of claim 19 wherein the following monomers are reacted: 1-vinyl-3-acetoxyphenyl; 1-vinyl-4-acetoxyphenyl; and an alicyclic acrylate.

33. The method of claim 32 wherein the acrylate compound is methyladamantyl acrylate or methyladamantyl methacrylate.
